(19) United States
(12) Patent Application Publication
(10) Pub. No.: US 2011/0198616 A1
(43) Pub. Date: Aug. 18, 2011

(54) SEMICONDUCTOR DEVICE AND METHOD FOR MANUFACTURING SAME

(76) Inventor: Kenya Yamashita, Hyogo (JP)

(21) Appl. No.: 13/124,420

(22) PCT Filed: Oct. 8, 2009
(86) PCT No.: PCT/JP2009/005249

§ 371 Date: Apr. 15, 2011

(30) Foreign Application Priority Data
Oct. 17, 2008 (JP) 2008-268508

(51) Int. Cl. H01L 27/088; H01L 21/336

(52) U.S. Cl. 257/77; 438/268; 257/E27.06; 257/E21.418

(57) ABSTRACT

Each unit cell includes: a drift layer 3 made of an n-type wide bandgap semiconductor formed on a substrate 2 made of an n-type wide bandgap semiconductor; a p-type well 4a provided in the driwhoseft layer 3; a first n-type impurity region 5 provided in the well 4a; a surface channel layer 7b formed at least on a surface of the well so as to connect together the first n-type impurity region 5 and the drift layer 3; a second n-type impurity region 7a provided in a surface region of the well which is under the surface channel layer and which spans the first n-type impurity region 5 and the drift layer 3, the second n-type impurity region 7a having an impurity concentration generally equal to or greater than an impurity concentration of the well 4a; and a third n-type impurity region formed in a surface region of the drift layer 3 adjacent to the second n-type impurity region 7a.

### TECHNICAL FIELD

The present invention relates to a semiconductor device, and more particularly to a silicon carbide semiconductor device and a method for manufacturing the same.

### BACKGROUND ART

Wide bandgap semiconductors are drawing public attention as semiconductor materials of semiconductor devices whose breakdown voltage is high and which are capable of conducting large currents therethrough (power devices). Among other wide bandgap semiconductors, silicon carbide (SiC) has a particularly high breakdown electric field, and is therefore expected as a semiconductor that is most suitable for next-generation low-loss power devices. Because good-quality silicon dioxide (SiO₂) films can be formed through thermal oxidation on SiC, insulated gate-type SiC-power MOSFETs using such silicon dioxide films as gate insulating films have been developed.

When an SiC-power MOSFET is manufactured, the conductivity of the semiconductor is controlled by using an ion implantation method. In the process, it is necessary to perform an activation annealing step of subjecting SiC to a heat treatment at a high temperature so as to restore crystal defects and activate impurities. Particularly, where aluminum ions are implanted into silicon carbide in order to form p-type impurity regions, it is necessary to subject a silicon carbide substrate to a heat treatment at a high temperature exceeding 1600° C. in order to restore the crystal structure.

However, even if a heat treatment is performed at such a high temperature, the crystallinity of the silicon carbide semiconductor is not completely restored, with disturbance of crystallinity remaining in some parts. As a result, if a gate insulating film is formed through thermal oxidation on a substrate with disturbed crystallinity, it is not possible to obtain a desirable SiO₂/SiC interface.

Specifically, the channel mobility lowers. Therefore, the channel resistance of the SiC-power MOSFET increases, thus failing to sufficiently bring out the low-loss property which SiC naturally has. Since it is difficult to obtain an oxide film or an SiO₂/SiC interface which satisfies predetermined characteristics, the production yield of the oxide film lowers extremely. Such a problem is not limited to aluminum ions, but it similarly occurs also when boron or another p-type impurity is used.

In order to solve this problem, Patent Document No. 1 proposes a vertical SiC-power MOSFET having a structure shown in FIG. 10. The SiC-power MOSFET shown in FIG. 10 includes a substrate 2 made of an SiC semiconductor, and an n-type drift layer 3 provided on the substrate 2. A p-type well 4a is provided in the drift layer 3. Moreover, an n-type source region 5 and a p-type contact region 4b are provided in the well 4a. The source region 5 and the contact region 4b are connected, with ohmic contact, to a source electrode 6 provided on the surface of the drift layer 3.

A channel layer 27 is provided on the surface of the drift layer 3 so as to connect together the source regions 5. The channel layer 27 includes a boundary portion 27a in the vicinity of a gate insulating film 8a and a boundary portion 27b in the vicinity of the drift layer 3, with the impurity concentration of the boundary portion 27a being lower than the impurity concentration of the boundary portion 27b.

According to Patent Document No. 1, the channel resistance of the vertical SiC-power MOSFET in the ON state includes the accumulation channel resistance (Rchannel) formed in the channel layer, and the accumulation drift resistance (the internal resistance, Racc-drift) in the channel layer. With the structure of FIG. 10, since the boundary portion 27a has a low impurity concentration, the accumulated carrier is formed in a region slightly distant from the SiO₂/SiC interface, avoiding the influence from the disturbance of crystallinity in the SiO₂/SiC interface, and it is therefore possible to reduce the accumulation channel resistance. By increasing the impurity concentration of the boundary portion 27b, it is possible to reduce the accumulation drift resistance. It is stated that it is therefore possible to effectively reduce the channel resistance as compared with a case where a single channel layer is used.

On the other hand, it is required of an SiC-power MOSFET that the reliability of the gate insulating film in the OFF state is sufficiently high. With an SiC-power MOSFET, if a high voltage is applied to the drain electrode in the OFF state, a high electric field is applied to the gate insulating film over the area between the wells. Particularly, an electric field of the highest intensity is applied to the gate insulating film above a point R that is located in the middle between the wells 4a shown in FIG. 10. Therefore, the applied electric field intensity is designed so that the gate insulating film over the point R is not broken. Breakdown of the gate insulating film can give a serious influence on the power circuit.

Patent Document No. 2 discloses a technique of suppressing the localization of electric field at the point R by providing an accumulated channel, i.e., an n-type channel region 28, over the p-type well 4a while providing no high-concentration n-type impurity region in the vicinity of the surface layer of the drift layer 3 between the wells 4a, as shown in FIG. 11, in order to reduce the channel resistance.

### CITATION LIST

### Patent Literature

Patent Document No. 1: Japanese Laid-Open Patent Publication No. 2002-270839
Patent Document No. 2: Japanese Laid-Open Patent Publication No. 2004-335917

### SUMMARY OF INVENTION

### Technical Problem

However, a study by the present inventor has revealed that, if the boundary portion 27b having a high impurity concentration is provided on the surface of the drift layer 3 as shown in FIG. 10, there are problems, including: (1) an increase in the drain leak in the OFF state; (2) a decrease in the breakdown voltage in the OFF state; (3) breakdown of the gate insulating film or occurrence of leak current in the gate insulating film due to a high drain electric field in the OFF state; and (4) a decrease in the threshold voltage.

Specifically, with the structure shown in FIG. 10, the impurity concentration of the boundary portion 27b of the channel layer 27 is set to be generally equal to the surface layer concentration of the well 4a directly under the boundary portion 27b. This is because unless it is set to this value, the threshold voltage (Vth) cannot be made about 4V. As a typical example, where the concentration of the well 4a is set to 10¹⁸ cm⁻³, the concentration of the boundary layer 27b needs to be set to 10¹⁷ cm⁻³ or more and 10¹⁹ cm⁻³ or less in order for the threshold voltage to be about 4 V, though it also depends on the thickness of the boundary layer 27b. This concentration is greater than the concentration of the drift layer 3 by an order of magnitude or more.

If the boundary layer 27b which is an n-type impurity region having such a high concentration is provided on the drift layer 3 between the wells 4a, a high electric field localizes at the boundary layer 27b when a high voltage is applied to a drain electrode 1. As a result, avalanche breakdown occurs, and particularly with a MOSFET of a short gate length having a gate length shorter than 1 μm, the short channel effect is likely to occur because the voltage barrier of the source drops trailing the drain electric field. Therefore, the drain leak increases, and the threshold voltage Vth of the device decreases. If the electric field applied to the boundary layer 27b increases, the electric field intensity applied to the gate insulating film located directly above the boundary layer 27b also increases, thereby causing problems such as an increase in the gate leak or breakdown of the gate insulating film. Particularly, the localization of the electric field at the point R of the gate insulating film becomes pronounced.

On the other hand, in a case where no n-type impurity region is formed over the drift layer 3 between the wells 4a as with the structure of the MOSFET shown in FIG. 11 disclosed in Patent Document No. 2, the electric field localization at the point R is reduced. However, since a channel region 28 is formed by implanting nitrogen into the wells 4a at a high concentration, crystal defects remain even if activation annealing is performed to restore crystallinity. Therefore, even if the gate insulating film 8a is formed on such a surface, a desirable SiO₂/SiC interface cannot be obtained, and the channel resistance of the MOSFET increases.

Moreover, since the concentration of the wells 4a is higher than the drift layer 3, a depletion layer 3d is formed in the drift layer 3 even when the MOSFET is in the ON state. Therefore, as indicated by arrows in FIG. 11, electrons passing through the channel region 28 are prevented from flowing into the drift layer 3 by the depletion layer 3d, thus substantially elongating the channel. Thus, the channel resistance increases.

The present invention has been made in order to solve at least one of such problems with the conventional techniques, and has an object to provide a wide bandgap semiconductor device with which it is possible to reduce the channel resistance in the ON state and to improve the breakdown voltage in the OFF state, thus improving the reliability.

### Solution to Problem

A semiconductor device of the present invention includes a plurality of unit cells arranged at least one-dimensionally, each unit cell including: a substrate made of an n-type wide bandgap semiconductor; a drift layer formed on the substrate and made of the n-type wide bandgap semiconductor; a p-type well provided in the drift layer; a first n-type impurity region provided in the well; a surface channel layer formed at least on a surface of the well so as to connect together the first n-type impurity region and the drift layer; a second n-type impurity region provided in a surface region of the well which is under the surface channel layer and which spans the first n-type impurity region and the drift layer, the second n-type impurity region having an impurity concentration generally equal to or greater than an impurity concentration of the well; a third n-type impurity region formed in a surface region of the drift layer adjacent to the second n-type impurity region; a gate insulating film formed on the surface channel layer; a gate electrode formed on the gate insulating film; a source electrode electrically connected to the first n-type impurity region; and a drain electrode provided on one surface of the substrate which is opposite to a surface thereof on which the drift layer is formed.

In a preferred embodiment, the surface channel layer contains an n-type impurity.

In a preferred embodiment, the surface channel layer contains a p-type impurity.

In a preferred embodiment, an impurity concentration of the n-type impurity or the p-type impurity is 1×10¹⁶ cm⁻³ or less.

In a preferred embodiment, each unit cell includes a fourth n-type impurity region formed in a surface region of the drift layer between the third n-type impurity region thereof and a third n-type impurity region of an adjacent unit cell; and an impurity concentration of the fourth n-type impurity region is lower than an impurity concentration of the third n-type impurity region and is generally equal to or greater than an impurity concentration of the drift layer.

In a preferred embodiment, the semiconductor device further includes a fifth n-type impurity region formed at a position in the drift layer that is adjacent to the fourth n-type impurity region and that includes an apex of the unit cell; and an impurity concentration of the fifth n-type impurity region is lower than the impurity concentration of the fourth n-type impurity region.

In a preferred embodiment, as each unit cell is seen from a surface side of the drift layer, the well has a generally rectangular shape, and the third n-type impurity region is not provided at corners of the rectangular shape of the well.

In a preferred embodiment, as each unit cell is seen from a surface side of the drift layer, the third n-type impurity region continuously surrounds the well.

In a preferred embodiment, a depth of the third n-type impurity region is smaller than a depth of the first n-type impurity region.

In a preferred embodiment, a depth of the third n-type impurity region is smaller than a width of the second n-type impurity region in a direction in which the plurality of unit cells are arranged.

In a preferred embodiment, a depth of the third n-type impurity region is smaller than a depth of the well.

In a preferred embodiment, an expression:

$$Lg ≧ \sqrt{\frac{2 \cdot ɛ \cdot Na \cdot Vbi}{q \cdot Next \cdot ( Na + Next )}} \qquad [ Expression 1 ]$$

is satisfied, where Nₑₓₜ denotes an impurity concentration of the third n-type impurity region, Na denotes the impurity concentration of the well, ∈ denotes a relative dielectric constant of silicon carbide, q denotes an elementary electric charge, Vbi denotes an internal potential of a junction portion between the second n-type impurity region and the third n-type impurity region, and Lg denotes a channel length of a channel formed in the surface channel layer.

In a preferred embodiment, an impurity concentration of the third n-type impurity region gradually decreases away from the second n-type impurity region in a direction in which the plurality of unit cells are arranged.

In a preferred embodiment, a concentration of the third n-type impurity region gradually decreases away from a surface of the drift layer.

A method for manufacturing a semiconductor device of the present invention includes the steps of: (A) preparing a substrate made of an n-type wide bandgap semiconductor in which a drift layer made of an n-type wide bandgap semiconductor is provided; (B) forming a well mask on the drift layer; (C) forming a p-type well in the drift layer by implanting a p-type impurity using the well mask; (D) implanting an n-type impurity using the well mask from a vertical direction and from an inclined direction with respect to the substrate, thereby forming an impurity region in the drift layer, the impurity region including a region to be a first n-type impurity region and a second n-type impurity region, and forming a third n-type impurity region in a portion of the drift layer under the well mask; (E) forming a first n-type impurity region mask on the drift layer in a self-aligned manner with respect to the well mask; (F) implanting an n-type impurity using the first n-type impurity region mask, thereby forming the first n-type impurity region in the drift layer, thus delimiting the second n-type impurity region; (G) removing the first n-type impurity region mask and the well mask; (H) performing an activation annealing process on the drift layer; (I) forming a surface channel layer having a low impurity concentration by epitaxial growth on the second n-type impurity region and the third n-type impurity region so as to be in contact with the first n-type impurity region and the well; (J) forming a gate insulating film on a surface of the surface channel layer; (K) forming a gate electrode on the gate insulating film; and (L) forming a source electrode and a drain electrode so as to be in contact with the first n-type impurity region and the substrate, respectively.

In a preferred embodiment, in the step (D), the third n-type impurity region is formed in the portion of the drift layer under the well mask by implanting the n-type impurity from a direction inclined with respect to the substrate within a plane perpendicular to a side that defines an opening shape of the well mask.

In a preferred embodiment, in the step (D), the third n-type impurity region is formed in the portion of the drift layer under the well mask by continuously rotating the substrate while implanting the n-type impurity from a direction inclined with respect to the substrate.

In a preferred embodiment, in the step (I), the surface channel layer is formed while an impurity gas other than a material gas of SiC is not intentionally supplied.

In a preferred embodiment, in the step (D), the third n-type impurity region is formed in the portion of the drift layer under the well mask by rotating the substrate stepwise while implanting the n-type impurity from a direction inclined with respect to the substrate. More specifically, the n-type impurity is implanted into the substrate while supporting the substrate so that the normal is unparallel to the direction in which the ion beam is applied, after which the substrate is rotated by θ=360°/n (n is an integer of 2 or more) using the normal as the axis. Then, the n-type impurity is implanted into the substrate, and the substrate is rotated by θ=360°/n (n is an integer of 2 or more) using the normal as the axis. By performing the implantation n times while rotating the substrate (n−1) times, the third n-type impurity region is formed in a portion of the drift layer under the well mask. The implantation may be performed more than n times, and the substrate may be rotated more than (n−1) times.

In a preferred embodiment, in the step (I), the surface channel layer is formed while a material gas of SiC and a gas to be an n-type impurity or p-type impurity are supplied.

### Advantageous Effects of Invention

According to the present invention, since the third n-type impurity region is provided, the depletion layer which is formed in the drift layer by the contact with the well does not extend to the position where the third n-type impurity region is provided because of the carrier supplied from the third n-type impurity region. Therefore, the channel length does not extend, and electrons can flow into the drift layer through the third n-type impurity region. Thus, the channel resistance is effectively reduced. Since the surface channel layer is provided, there is substantially no disturbance of crystallinity in the vicinity of the interface between the surface channel layer and the gate insulating film, and the channel resistance is low.

Since the fourth n-type impurity region is provided, it is possible to suppress the localization of an electric field in the gate insulating film at a position in the middle between wells because of the voltage applied to the drain electrode while the semiconductor device is in the OFF state, and it is possible to improve the breakdown voltage and improve the reliability.

### BRIEF DESCRIPTION OF DRAWINGS

FIG. 1 shows diagrams showing a semiconductor device according to a first embodiment of the present invention, wherein (a) is a cross-sectional view, (b) is a plan view showing the arrangement and structure of unit cells at the drift layer, and (c) is a plan view showing the structure inside the well.

FIG. 2 is an enlarged cross-sectional view showing the structure of the drift layer.

FIGS. 3(a) to 3(l) are cross-sectional views showing steps of a method for manufacturing the semiconductor device shown in FIG. 1.

FIGS. 4(a) to 4(c) are diagrams showing an ion implantation step for forming a third n-type impurity region.

FIG. 5 is another plan view showing the arrangement and structure of unit cells at the drift layer.

FIGS. 6(a) to 6(i) are cross-sectional views showing steps of a method for manufacturing the semiconductor device shown in FIG. 1.

FIG. 7(a) is a cross-sectional view showing a semiconductor device according to a second embodiment of the present invention, and FIG. 7(b) is a plan view showing the arrangement and structure of unit cells at the drift layer.

FIG. 8 is a plan view illustrating the size of unit cells of a MOSFET used in an experimental example.

FIG. 9 is a graph showing the relationship between the third n-type impurity concentration, the impurity concentration of the wells, and the channel resistance.

FIG. 10 is a cross-sectional view showing a structure of a conventional semiconductor device.

FIG. 11 is a cross-sectional view showing a structure of another conventional semiconductor device.

### DESCRIPTION OF EMBODIMENTS

### First Embodiment

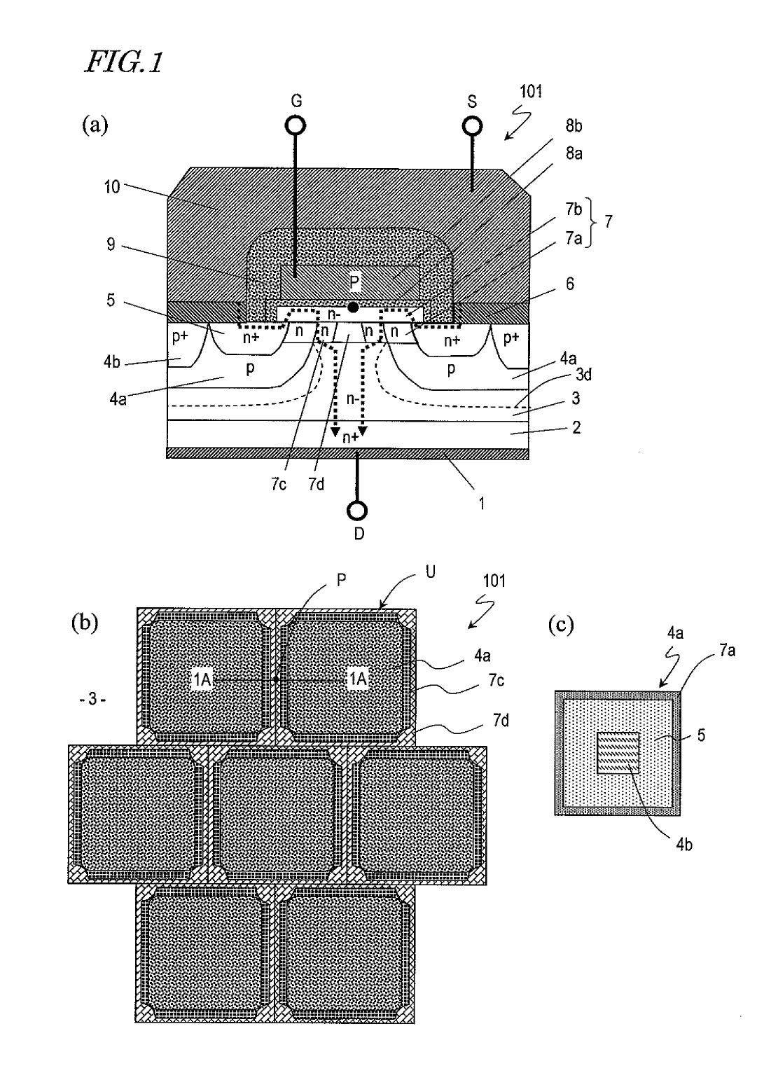

A semiconductor device according to a first embodiment of the present invention will now be described. In the present embodiment, the present invention will be described with reference to an example of a double implanted MOSFET. FIG. 1(a) shows a cross-sectional structure of a part of a double implanted MOSFET 101, and FIG. 1(b) shows a planar structure of a drift layer 3 of the MOSFET 101. FIG. 1(a) shows the cross-sectional structure taken along line 1A-1A of FIG. 1(b). The MOSFET 101 includes a plurality of unit cells U. As shown in FIG. 1(b), on the drift layer 3, each unit cell U has a rectangular shape, for example, and the unit cells U are arranged in a staggered pattern. More specifically, the unit cells U are arranged two-dimensionally, and the unit cells U are arranged with ½ period shifts in one direction. Note however that it is only required that the unit cells U are arranged at least one-dimensionally because the effects of the present invention can be obtained as long as the unit cells U are arranged so as to be adjacent to one another in the MOSFET 101 as will be described below. The shape of the unit cell U on the drift layer 3 may be a shape other than a rectangular shape, e.g., a hexagonal shape.

The unit cell U of the MOSFET 101 includes a substrate 2 made of a wide bandgap semiconductor, and the drift layer 3 made of a wide bandgap semiconductor formed on the substrate 2. In the present specification, a wide bandgap semiconductor refers to a semiconductor made of SiC, GaN, or the like. In the present embodiment, the substrate 2 is, for example, a low-resistance SiC substrate containing 1×10¹⁸ cm⁻³ or more of an n-type impurity (nitrogen, phosphorus, arsenic, or the like). The drift layer 3 is an SiC semiconductor layer doped with about 1×10¹⁴ cm⁻³ or more and about 1×10¹⁶ cm⁻³ or less of a p-type impurity (e.g., aluminum). The drift layer 3 can be formed for example through epitaxial growth by a CVD method, or the like, on the substrate 2.

In a portion of the drift layer 3, the p-type wells 4a are provided so as to extend from the surface toward the inside of the drift layer 3. The well 4a is doped with, for example, 1×10¹⁶ cm⁻³ or more and 1×10¹⁸ cm⁻³ or less of a p-type impurity. In order to realize a high breakdown voltage, the concentration of the well 4a is preferably 1×10¹⁷ cm⁻³ or more and 1×10¹⁹ cm⁻³ or less.

In a portion of the well 4a, a p⁺-type contact region 4b and a source region 5 which is a first n-type impurity region are formed so as to be adjacent to each other. The contact region 4b and the source region 5 are formed so as to extend from the surface toward the inside of the well 4a. The p⁺-type contact region 4b is doped with about 5×10¹⁹ cm⁻³ of a p-type impurity, and the source region 5 is doped with 1×10¹⁹ cm⁻³ or more and 1×10²⁰ cm⁻³ or less of an n-type impurity.

A surface channel layer 7b is formed at least on the surface of the well 4a so as to connect together the source region 5 and the drift layer 3. The surface channel layer 7b has the n-type conductivity, and contains a slight amount of at least one of n-type nitrogen, phosphorus and antimony. The impurity concentration is preferably low, and is preferably lower than the amount of intentional doping. For example, it is preferably about an amount by which nitrogen, phosphorus and antimony contained in the background atmosphere, or the like, are inadvertently taken in during epitaxial crystal growth by a CVD method, or the like. With such a surface channel layer 7b, the threshold voltage of the MOSFET is no longer substantially dependent on the impurity concentration of the surface channel layer. When not intentionally doped with an n-type impurity, the impurity concentration of a surface channel layer 7 is preferably 1×10¹⁶ cm⁻³ or less, though it also depends on the growth conditions. It is more preferred that the impurity concentration of the surface channel layer 7 can be suppressed to be 1×10¹⁵ cm⁻³ or less. Note however that the impurity concentration of the surface channel layer 7 being 1×10¹⁴ cm⁻³ or less is not preferable because the channel layer itself then becomes a high-resistance layer, and in such a case it is preferably set in a concentration range to be shown below.

Where the surface channel layer 7b is formed by intentionally doping it with an n-type impurity, the impurity concentration is preferably 1×10¹⁴ cm⁻³ or more and 1×10¹⁶ cm⁻³ or less taking into consideration the stability of the threshold voltage, i.e., so that the impurity concentration can be controlled appropriately. Since the impurity concentration of the well 4a is typically set to 1×10¹⁷ cm⁻³ or more, the impurity concentration of the surface channel layer 7b can reliably be made lower than the impurity concentration of the well 4a so that the threshold voltage is unlikely to fluctuate by setting the impurity concentration of the surface channel layer 7b to 1×10¹⁶ cm⁻³ or less, which is smaller than the impurity concentration of the well 4a by an order of magnitude or more. If the impurity concentration of the surface channel layer 7b is 1×10¹⁴ cm⁻³ or more, it is possible to suppress the resistance with the semiconductor region connected to the surface channel layer 7b to such a small value that it is virtually negligible.

The surface channel layer 7b has the p-type conductivity, and may contain a slight amount of at least one of boron and aluminum. Also in such a case, the impurity concentration is preferably low, and is preferably lower than the amount of intentional doping. With such a surface channel layer 7b, the threshold voltage of the MOSFET is no longer substantially dependent on the impurity concentration of the surface channel layer. When not intentionally doped with an impurity, the p-type impurity concentration of the surface channel layer 7b is preferably 1×10¹⁶ cm⁻³ or less.

Alternatively, the surface channel layer 7b may be formed by intentionally doping it with a p-type impurity. In such a case, the impurity concentration is preferably 1×10¹⁴ cm⁻³ or more and 1×10¹⁶ cm⁻³ or less taking into consideration the stability of the threshold voltage. As with n-type, the threshold voltage is unlikely to fluctuate if the impurity concentration of the surface channel layer 7b is 1×10¹⁶ cm⁻³ or less. The p-type impurity concentration of the surface channel layer 7b is preferably as low as possible because then the carrier scattering decreases and the channel mobility increases. While the lower limit of the p-type impurity concentration depends on the crystal growth facility, the channel mobility is saturated at about 1×10¹⁴ cm⁻³. Therefore, the impurity concentration may be 1×10¹⁴ cm⁻³ or more.

When the surface channel layer 7b is of the p-type, it forms a pn junction with the source region 5, thus making it more difficult for the current to flow from the source region 5 to the surface of the surface channel layer 7b. A pn junction is formed also between the surface channel layer 7b and the wells 4a. Therefore, it is preferred to form an n-type impurity region by ion implantation, or the like, in the surface channel layer 7b so that the source region 5 and the wells 4a are connected with the vicinity of the surface of the surface channel layer 7b by the n-type impurity region formed.

A second n-type impurity region 7a is provided in a surface region of the well 4a which is under the surface channel layer 7b and which spans the source region 5 and the drift layer 3. It is preferred that the impurity concentration of the second n-type impurity region 7a is generally equal to or greater than the impurity concentration of the well 4a. Specifically, where the impurity concentration of the well 4a is about 1×10¹⁷ cm⁻³, which is a typical value, the threshold voltage can be controlled to about 4 V, which is an appropriate value, by adjusting the impurity concentration of the second impurity region 7a to about 1.5×10¹⁷ cm⁻³. Where the impurity concentration of the well 4a is about 1×10¹⁹ cm⁻³, the threshold voltage can be controlled to about 4 V by adjusting the impurity concentration of the second impurity region 7a to about 5×10¹⁸ cm⁻³. Thus, when the impurity concentration range of the well 4a is taken into consideration, the threshold voltage can be controlled to about 4 V by adjusting the impurity concentration of the second impurity region 7a to 5×10¹⁶ cm⁻³ or more and 1×10¹⁹ cm⁻³ or less. Also when it is desirable to control the threshold voltage to a value that is slightly lower or higher than 4 V, it is possible to realize an intended threshold value by adjusting the impurity concentration of the second impurity region 7a within this range.

The second n-type impurity region 7a and the surface channel layer 7b together form the channel 7. The thickness of the surface channel layer 7b is preferably 10 nm or more and 200 nm or less. The threshold value of the MOSFET 101 is controlled substantially by the impurity concentration, the thickness or more essentially the dose of the second impurity region 7a. Note however that the influence of the thickness of the surface channel layer 7b on the threshold value is smaller than that of the concentration. The thickness of the surface channel layer 7b is greatly restricted by the manufacturing process of the MOSFET 101.

If the surface channel layer 7b has a thickness of about 10 nm before the formation of the gate oxide film, an interface between the gate oxide film and the surface channel layer and a surface of the gate oxide film, which are ideally smooth, can be obtained between the gate oxide film and the surface channel layer 7b. However, if the thickness of the surface channel layer 7b is smaller than 10 nm, it is difficult to obtain a smooth interface or gate oxide film surface. Where the thickness of the surface channel layer 7b is 200 nm or more, the electric field on the drain side seeps into the surface channel layer 7b, adversely influencing the channel modulation. Specifically, the short channel effect is pronounced.

Therefore, also taking into consideration the process margin, it is preferred that the thickness of the surface channel layer 7b is 30 nm or more and 100 nm or less. With the thickness in this range, it is possible to stably manufacture the MOSFET 101 having predetermined characteristics even if errors caused by the manufacturing process are taken into consideration.

It is preferred that the sheet concentration of the second n-type impurity region 7a is 10¹² cm⁻². The threshold voltage of the MOSFET 101 can also be controlled by performing concentration control of the second n-type impurity region 7a. For example, where the thickness of the surface channel layer 7b is set to 50 nm, the threshold voltage can be controlled to 3 V or more and 6 V or less by changing the sheet concentration of the second n-type impurity region 7a in the range of 1×10¹² cm⁻² or more and 5×10¹² cm⁻² or less. By using ion implantation, the fluctuation of the impurity concentration of the second n-type impurity region 7a can be suppressed to 1% or less, and it is therefore possible to control the threshold voltage with high precision.

Thus, the source region 5, the contact region 4b and the second n-type impurity region 7a are formed in the wells 4a. FIG. 1(c) is a plan view showing the structure of the well 4a as seen from the surface of the drift layer 3. The contact region 4b is surrounded by the source region 5, and the source region 5 is surrounded by the second n-type impurity region 7a.

As shown in FIG. 1(a), a third n-type impurity region 7c is provided in the surface region of the drift layer 3 so as to be adjacent to the second n-type impurity region 7a. Since the impurity concentration of the third n-type impurity region 7c is not compensated for by the impurity of the well 4a, there is an effect of reducing the channel resistance by setting it to 5×10¹⁶ cm⁻³ or more and 5×10¹⁷ cm⁻³ or less, which is generally equal to the impurity concentration of the well 4a. It is possible to obtain an effect of further reducing the channel resistance by setting the impurity concentration of the third n-type impurity region 7c to be higher, e.g., about 1×10¹⁸ cm⁻³. However, the electric field may then localize at the third n-type impurity region 7c, thereby causing the gate leak or breakdown of the gate insulating film.

Each unit cell U includes a fourth n-type impurity region 7d formed in the surface region of the drift layer 3 between the third n-type impurity region 7c thereof and the third n-type impurity region 7c of an adjacent unit cell U. It is preferred that the impurity concentration of the fourth n-type impurity region 7d is lower than the impurity concentration of the third n-type impurity region 7c and is generally equal to or greater than the impurity concentration of the drift layer 3.

As shown in FIG. 1(b), the third n-type impurity region 7c is surrounding the well 4a except for the four corners of the well 4a. In other words, the third n-type impurity region 7c is not provided at the four corners of the well 4a.

The gate insulating film 8a is provided on the surface channel layer 7b. A gate electrode 8b is provided on the gate insulating film 8a. The gate insulating film 8a is made of silicon oxide, for example, and may be formed by depositing and patterning silicon oxide or performing thermal oxidation on the surface of the surface channel layer 7b. The gate electrode 8b is made of polysilicon, for example.

The source electrode 6 is provided so as to be electrically connected to the source region 5 and the contact region 4b. The drain electrode 1 is provided on one surface of the substrate 2 on which the drift layer 3 is not provided. The source electrode 6 and the drain electrode 1 are made of an Ni alloy, for example, and is subjected to a heat treatment so as to be in ohmic contact with the source region 5, the contact region 4b and the substrate 2.

An interlayer insulating film 9 is provided so as to cover the gate electrode 8b, and a contact is formed in the interlayer insulating film 9 so that the source electrode is exposed therethrough. The source electrode 6 is electrically connected to a source line 10. The source electrodes 6 of other unit cells are also connected to the source line 10.

In each unit cell of the MOSFET 101 having such a configuration, if a bias voltage greater than or equal to the threshold voltage is applied to the gate electrode 8b in the presence of a predetermined voltage applied between the source electrode 6 and the drain electrode 1, electrons, which are carriers, travel from the source electrode 6 through the source region 5 and through the surface channel layer 7b in the vicinity of the interface between the surface channel layer 7b and the gate insulating film 8a, as indicated by arrows in FIG. 1(a). Since the surface channel layer 7b is formed by epitaxial growth, the impurity concentration is suppressed to be low. Moreover, since the activation annealing process is not performed, there is hardly any disturbance of crystallinity in the vicinity of the boundary with the gate insulating film 8a. Therefore, the channel resistance is low.

With the provision of the third n-type impurity region 7c, the depletion layer 3d which is formed in the drift layer 3 through contact with the well 4a is prevented by the carriers supplied from the third n-type impurity region 7c from extending to the position where the third n-type impurity region 7c is provided. Therefore, electrons traveling through the surface channel layer 7b can flow into the drift layer 3 through the third n-type impurity region 7c, and therefore the channel length does not extend as described above with reference to FIG. 11. Thus, the channel resistance is effectively reduced.

Each unit cell U includes the fourth n-type impurity region 7d which is formed in the surface region of the drift layer 3 between the third n-type impurity region 7c thereof and the third n-type impurity region 7c of an adjacent unit cell U. The impurity concentration of the fourth n-type impurity region 7d is lower than the impurity concentration of the third n-type impurity region 7c. This suppresses the problem that the depletion layers extending from adjacent wells 4a into the drift layer 3 reach a position below a point P in the middle between the wells 4a, thereby localizing the voltage applied to the drain electrode 1 at the point P while the MOSFET 101 is in the OFF state. Therefore, it is possible to improve the breakdown voltage of the MOSFET 101 and improve the reliability.

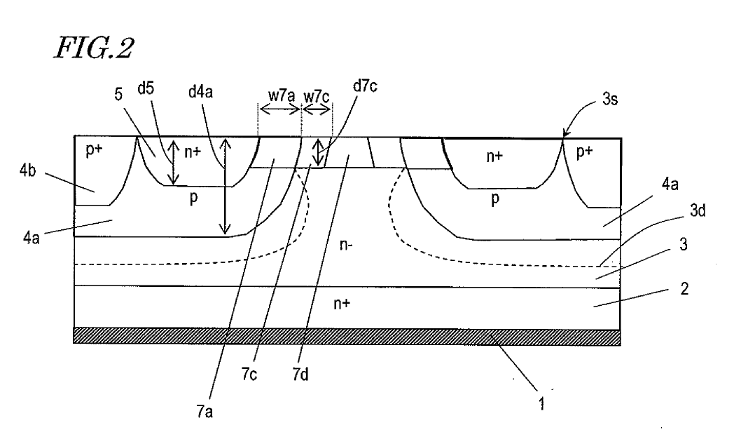

In order to reduce the accumulation drift resistance of the channel in the MOSFET 101 while exerting such effects as described above, it is preferred that the shape and the impurity concentration of the third n-type impurity region 7c satisfy predetermined conditions. Specifically, the depth d7c of the third n-type impurity region 7c is preferably smaller than the depth d4a of the well 4a as shown in FIG. 2.

A primary role of the third n-type impurity region 7c lies in the reduction of the accumulation drift resistance, and it is possible to reduce the accumulation drift resistance by increasing the impurity concentration in the vicinity of the surface channel layer 7b. Therefore, it is possible to obtain the effect of reducing the accumulation drift resistance whether the depth of the third n-type impurity region 7c is small or large. However, the OFF-state characteristics can be improved by setting the depth d7c of the third n-type impurity region 7c to be smaller than the depth d4a of the well 4a. Specifically, it is possible to improve the reliability in the gate insulating film 8a in the presence of a high voltage applied to the drain electrode 1, and to suppress problems such as the short channel effect and an increase in the drain leak due to a high electric field applied to the drain. Improving these characteristics is typically in a trade-off relationship with the reduction of the accumulation drift resistance. However, it is possible to achieve the reduction of the accumulation drift resistance and the improvement of these characteristics by reducing the depth d7c of the third n-type impurity region 7c so that a high voltage is not applied to the gate insulating film 8a in the OFF state of the MOSFET 101.

Moreover, it is preferred that the impurity concentration of the third n-type impurity region 7c gradually decreases away from the second n-type impurity region 7a in the direction in which the unit cells U are arranged. It is also preferred that the impurity concentration of the third n-type impurity region 7c gradually decreases away from the surface of the drift layer (toward the inside of the drift layer 3). Thus, the electric field intensity at the point P shown in FIG. 1 can be weakened, and it is possible to further improve the reliability in the gate insulating film 8a in the presence of a high voltage applied to the drain electrode 1 and to further suppress problems such as the short channel effect and an increase in the drain leak due to a high electric field applied to the drain.

The depth d7c of the third n-type impurity region 7c is generally equal to the width w7c of the third n-type impurity region in the direction in which the unit cells U are arranged, though it also depends on the method (process) of forming the third n-type impurity region 7c. That is, where an impurity region on an order of magnitude smaller than 1 μm is formed by implanting an impurity into a silicon carbide semiconductor, the depth of the impurity region to be formed and the horizontal extent thereof will be generally equal to each other.

Therefore, it is possible to reduce the width w7c of the third impurity region by reducing the depth d7c of the third impurity region 7c. Since the width w7a of the second n-type impurity region 7a in the direction in which the unit cells U are arranged is the channel length (Lg) of the MOSFET 101, it is possible to effectively reduce the accumulation drift resistance by setting the width w7c of the third impurity region, i.e., the depth d7c of the third impurity region 7c, to be smaller than the width w7a of the second n-type impurity region 7a in the direction in which the unit cells U are arranged.

It is preferred that the depth d7c of the third n-type impurity region 7c is smaller than the depth d5 of the first n-type impurity region 5. The third n-type impurity region 7c is formed by ion implantation because the carrier concentration of the well 4a may be influenced and the breakdown voltage, or the like, may be adversely influenced if the third n-type impurity region 7c is designed to be deeper than the first n-type impurity region 5.

It is preferred that the relationship below is satisfied, where Nₑₓₜ denotes the impurity concentration of the third n-type impurity region 7c, Na denotes the impurity concentration of the well 4a, ∈ denotes the relative dielectric constant of silicon carbide, q denotes the elementary electric charge, Vbi (built-in potential) denotes the internal potential of the junction portion between the second n-type impurity region 7a and the third n-type impurity region 7c, and Lg denotes the channel length of the channel formed in the surface channel layer 7b.

$$Lg ≧ \sqrt{\frac{2 \cdot ɛ \cdot Na \cdot Vbi}{q \cdot Next \cdot ( Na + Next )}} \qquad [ Expression 1 ]$$

By controlling the impurity concentration Nₑₓₜ of the third n-type impurity region 7c so as to satisfy the relationship of the expression above, it is possible to optimize the reduction of the accumulation drift resistance and the suppression of the electric field localization between JFETs, particularly at the point R, which are in a trade-off relationship.

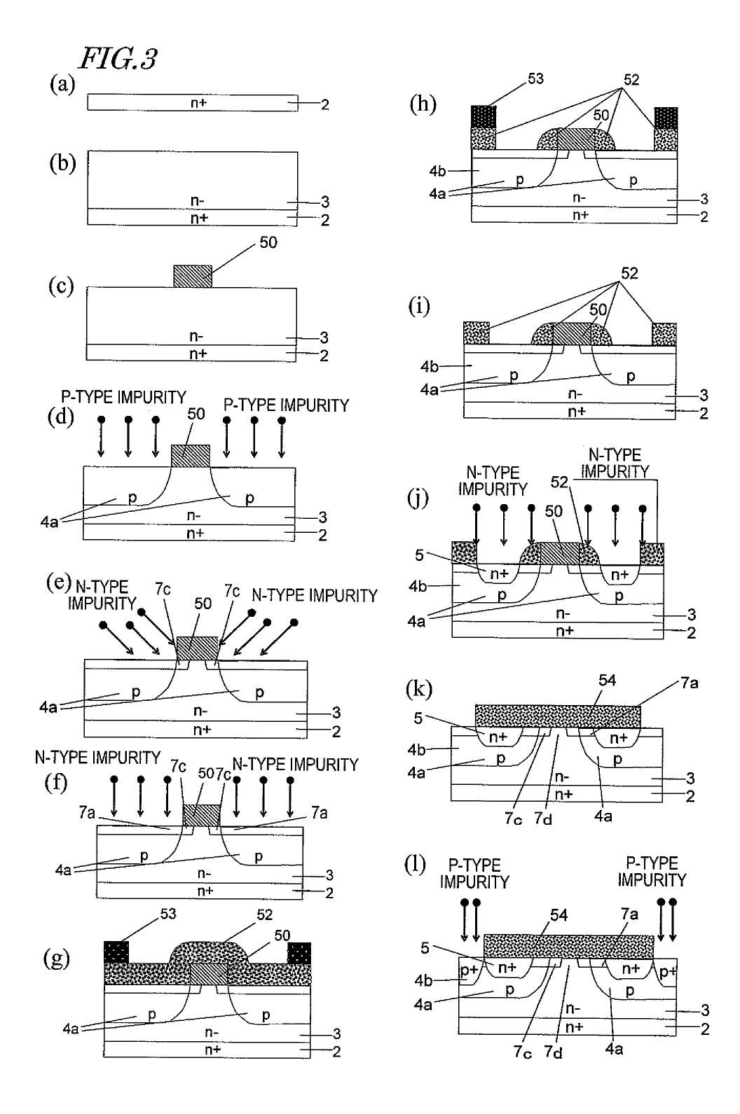

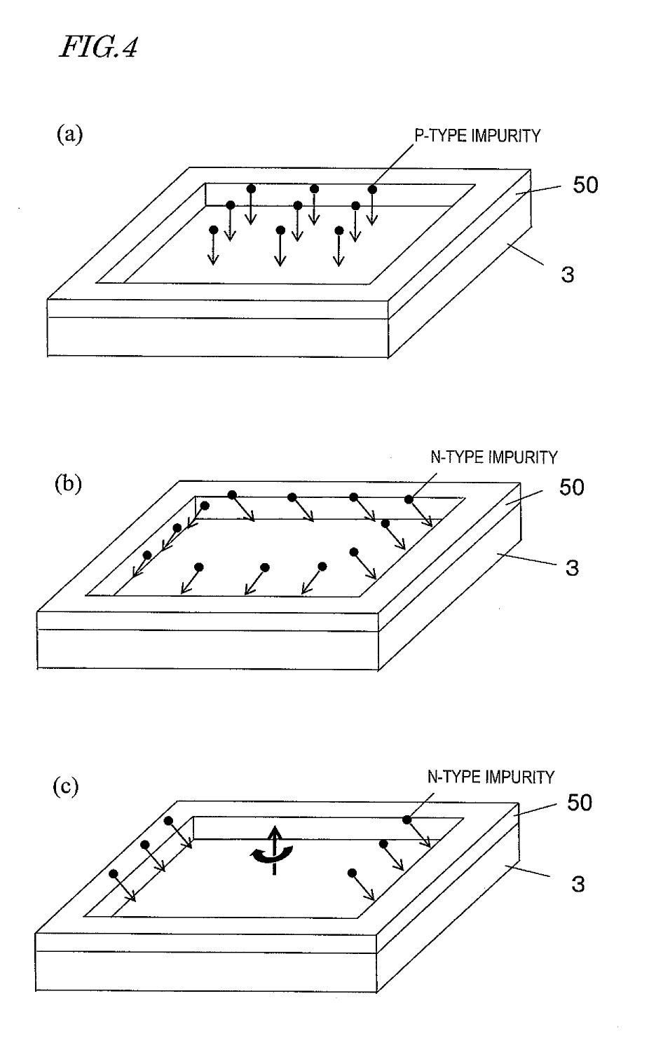

For example, the MOSFET 101 can be manufactured by the following method. First, as shown in FIG. 3(a), an SiC substrate is prepared as the substrate 2, which has an off angle of 8° from the (0001) plane of 4H-SiC, for example. As shown in FIG. 3(b), the drift layer 3 made of high-resistance SiC containing an n-type impurity at a lower concentration than the substrate 2 is formed by thermal CVD, or the like, on the principle plane of the substrate 2. The substrate 2 may be a low-off angle substrate whose plane orientation is 8° or less. For example, the drift layer 3 uses silane (SiH₄) and propane (C₃H₈) as material gases, hydrogen (H₂) as a carrier gas, and nitrogen (N₂) as a dopant gas. Where a MOSFET whose breakdown voltage is 1000 V is manufactured, for example, the impurity concentration of the high-resistance SiC layer 3 is preferably 1×10¹⁵ cm⁻³ or more and 1×10¹⁶ cm⁻³ or less, and the thickness thereof is preferably 10 μm or more.

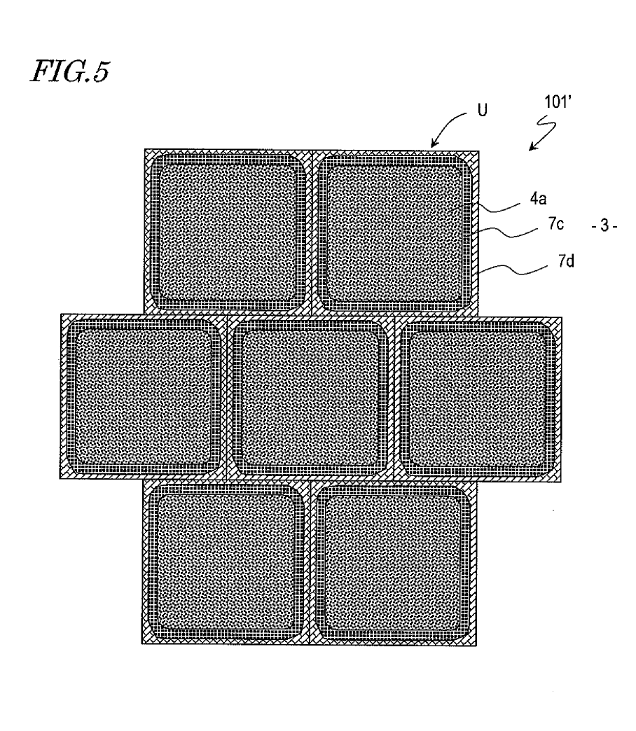

Next, as shown in FIG. 3(c), a well mask 50 is formed on the drift layer 3. First, a mask material which has a thickness of 1.5 μm and is capable of holding its shape at a high temperature of 500° C. or more is formed on the drift layer 3, and opening is provided by photolithography and dry etching only in a portion where the well 4a is to be formed. The mask material may be an oxide film, polysilicon, nitride film, etc. Other materials may be used as long as the materials do not alter at high temperatures. The thickness of the well mask 50 can be set to such a thickness that the implantation species does not penetrate the well mask 50 though it depends on the implantation energy of the ion implantation. Then, as shown in FIG. 3(d), aluminum or boron is implanted into the drift layer 3 while the substrate temperature is kept at 400° C. or more and 600° C. or less in order to reduce implantation defects. This is done by implanting ions vertically to the drift layer 3 as shown in FIG. 4(a). The concentration of the p-type impurity in the well 4a is normally 1×10¹⁷ cm⁻³ or more and 1×10¹⁸ cm⁻³ or less, and the depth of the well 4a is designed so that punch-through does not occur. For example, by implanting Al into the drift layer 3 under conditions of 5×10¹¹ cm⁻³ at 30 keV, 1.5×10¹² cm⁻³ at 70 keV, and 3×10¹² cm⁻³ at 20 keV, the impurity concentration of a region of drift layer 3 within a depth of 20 nm from the surface is set to about 3×10¹⁷ cm⁻³. Moreover, in order to achieve a breakdown voltage of 1500 V or more, implantation is performed with 6×10¹³ cm⁻³ at 500 keV, for example, so that the concentration in a deep portion at 0.55 μm is 3×10¹⁸ cm⁻³. Thus, the well 4a is formed in the drift layer 3.

Next, as shown in FIG. 3(e), a slant ion implantation is performed so as to form the third n-type impurity region 7c in a portion of the drift layer 3 under the well mask 50. In this process, in order to reduce implantation defects, the implantation is preferably performed while the substrate temperature is kept at 400° C. or more and 600° C. or less. As shown in FIG. 4(b), nitrogen is implanted into the drift layer 3 while the substrate 2 on which the drift layer 3 is formed is inclined so that impurity ions are applied to the drift layer 3 from a direction that is inclined with respect to the substrate 2 within a plane perpendicular to a side that defines the opening shape of the well mask 50, i.e., a side of the rectangular shape. For example, the impurity concentration is 10¹⁷ cm⁻³ or more and 10¹⁸ cm⁻³ or less, and the implantation depth is about 0.1 μm or more and about 0.3 μm or less. As shown in FIG. 4(b), the implantation is performed four times while rotating the substrate 2 by 90 degrees each time so that the third n-type impurity region 7c is formed under the four sides of the well mask 50 of the unit cell. Thus, the third n-type impurity region 7a is formed in the outside region excluding the four corners of the well 4a as shown in FIG. 1(b).

In this process, the substrate 2 may be continuously rotated using the normal as the rotation axis while the impurity is injected from a direction inclined with respect to the surface of the drift layer 3 as shown in FIG. 4(c). In such a case, it is possible to manufacture a MOSFET 101′ including the third n-type impurity region 7c which continuously surrounds the entire periphery of the well 4a as shown in FIG. 5.

Although the substrate temperature is preferably kept at a high temperature during implantation as described above, it may be difficult to continuously rotate the substrate while heating the substrate depending on the substrate heating scheme. In such a case, the substrate 2 may be rotated stepwise while implanting the impurity into the drift layer 3 from a direction inclined with respect to the surface of the drift layer 3 of the substrate 2. More specifically, an n-type impurity is implanted into the drift layer 3 of the substrate 2 while supporting the substrate 2 so that the normal is unparallel to the direction in which the impurity ions are applied, after which the substrate is rotated by θ=360°/n (n is an integer of 2 or more) using the normal as the axis. Then, an n-type impurity is implanted into the drift layer 3, and the substrate 2 is rotated by θ=360°/n (n is an integer of 2 or more) using the normal as the axis. By performing the implantation n times while rotating the substrate 2 (n−1) times, the third n-type impurity region 7c is formed in a portion of the drift layer 3 under the well mask 50. The implantation may be performed more than n times, and the substrate may be rotated more than (n−1) times.

Then, as shown in FIG. 3(f), ion implantation is performed from a direction perpendicular to the drift layer 3 to form an impurity region which includes regions to be the second impurity region 7a and the source region 5 in the drift layer 3. By implanting with an implantation energy of 30 keV and a dose of 10¹¹ cm⁻² or more and 10¹² cm⁻² or less using nitrogen as the implantation species, it is possible to control the threshold voltage to 3 V or more and 6 V or less. The implantation species may be an n-type impurity such as phosphorus and antimony, other than nitrogen. In such a case, the design is preferably such that the impurity profile will be similar to that with nitrogen.

Thus, by implanting in a self-aligned manner using the well mask 50 for the threshold voltage control, the implantation species is not implanted into the fourth n-type impurity region 7d. Therefore, it is possible to suppress the localization of the electric field at the fourth n-type impurity region 7d which increases the drain leak while the MOSFET is in the OFF state, and it is also possible to suppress the decrease in the breakdown voltage. Moreover, it is possible to suppress the increase in the leak through the gate insulating film or the breakdown of the gate insulating film due to a high drain electric field, and it is also possible to suppress the decrease in the threshold voltage.

Then, a mask for the source region 5 is formed. As shown in FIG. 3(g), a mask 52 is deposited across the entire surface of the drift layer 3, and photolithography is performed. In this process, a resist mask 53 is formed in a portion where the contact region 4b is to be formed in a subsequent step. As shown in FIG. 3(h), the thin film 52 is dry-etched using the resist mask 53, thereby providing an opening only in a portion to be the source region 5. In this process, it is possible to define the gate length in a self-aligned manner by forming a side wall on the side wall of the well mask 50 by anisotropy etching. Thus, it is possible to produce a minute-gate length transistor whose channel length Lg is about 0.5 μm or more and about 1 μm or less.

The resist mask 53 is removed as shown in FIG. 3(i), and the source region 5 is formed by implanting an n-type impurity into the drift layer 3 using the well mask 50 and the mask 52 as shown in FIG. 3(j). The impurity concentration of the source region 5 is set to 1×10¹⁹ cm⁻³ or more and 1×10²⁰ cm⁻³ or less so that an ohmic contact is obtained when electrodes are formed.

Then, the well mask 50 and the mask 52 are removed and a mask 54 is formed which defines the contact region 4b as shown in FIG. 3(k), and the p-type contact region 4b is formed by implanting aluminum into the drift layer 3 using the mask 54 as shown in FIG. 3(l). The impurity concentration of the contact region 4b is set to about 1×10²⁰ cm⁻³ so that an ohmic contact is obtained when electrodes are formed. After the implantation, the mask 54 is removed.

Note that when the impurity concentration of the well 4 increases due to the design and the dose of the ion implantation (FIG. 3(f)) for forming the n-type impurity region including regions to be the second impurity region 7a and the source region 5 is set to about 1×10¹² cm⁻² in order to obtain an appropriate threshold voltage (3 V), the contact resistance to the well 4a may increase. In such a case, after the resist mask 52 is removed (FIG. 3(k)), there may be added a step of etching the n-type impurity region which is the surface layer of the region to be the contact region 4b and which is a counter-doped region for the contact region 4b. Then, the mask 54 is formed as described above (FIG. 3(k)), and the p-type contact region 4b is formed by implanting aluminum into the drift layer 3 using the mask 54 as shown in FIG. 3(l). Thus, the increase in the contact resistance to the well 4a is suppressed. In such a case, the second impurity region 7a will be shallower than the contact region 4b (the bottom portion positioned closer to the substrate 2).

Also when the n-type impurity region is not etched, the depth of the second impurity region 7a is preferably shallower than the contact region 4b. In other words, the contact region 4b is preferably deeper than the second impurity region 7a. Then, the contact region 4b can contact the well 4a in an un-counter-doped region, and it is therefore possible to reduce the contact resistance to the well 4a.

After the mask 54 is removed, activation annealing is performed by holding the substrate 2 in an atmosphere of an inert gas such as argon at 1700° C. for 30 min in order to activate the impurity implanted into the drift layer 3. In this process, macrosteps whose height is about 10 nm or more and about 100 nm or less occur on the drift layer 3, thereby increasing the surface roughness and deteriorating the surface smoothness. Therefore, in order to prevent the deterioration of the surface flatness, it is preferred that the heat treatment is performed while the surface of the drift layer 3 is covered with a material which withstands high temperatures such as DLC (diamond-like carbon). Thus, the surface roughness can be suppressed to about 1 nm or more and about 10 nm or less.

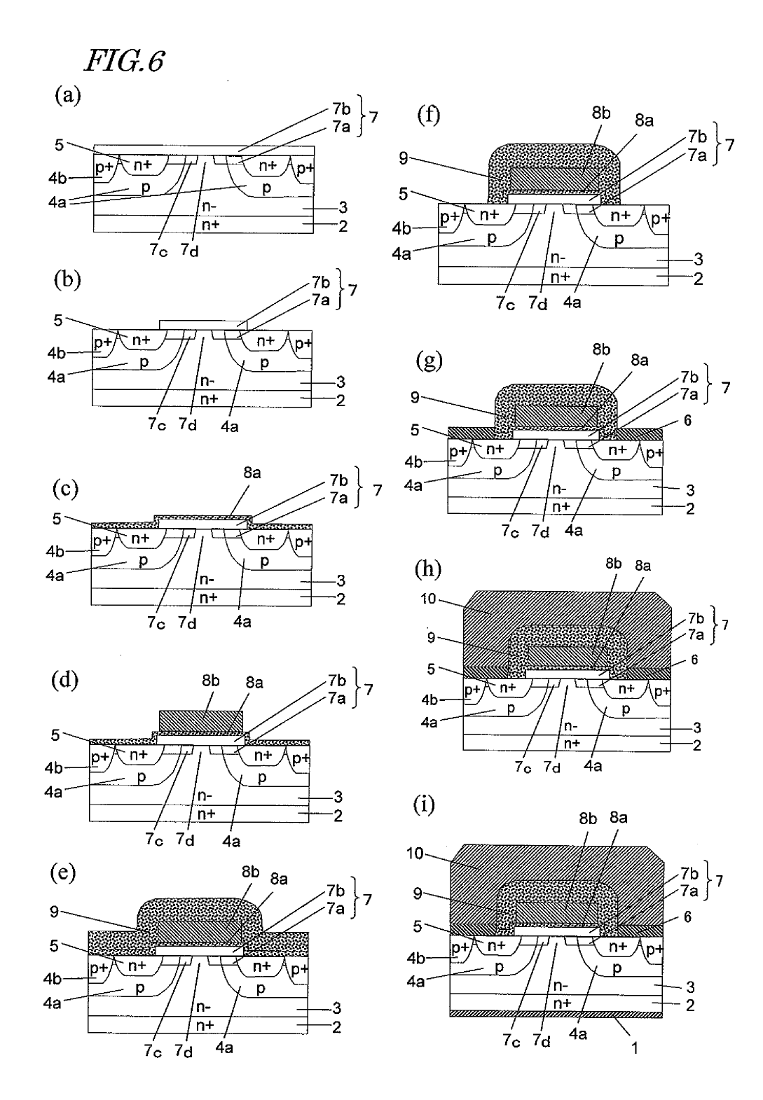

Next, as shown in FIG. 6(a), the surface channel layer 7b is epitaxially grown on the surface of the drift layer 3. The surface channel layer 7b can be formed in a similar manner to the drift layer 3, for example. Note however that the surface channel layer 7b is grown while an impurity is not intentionally added. Then, as shown in FIG. 6(b), the surface channel layer 7b present in a region where the source electrode is to be formed is removed, the surface of the patterned surface channel layer 7b is subjected to sacrificial oxidation, and the produced sacrificial oxide film is removed.

Then, as shown in FIG. 6(c), pre-cleaning (ordinary RCA cleaning) is performed to oxidize the surface of the drift layer 3 and the surface of the surface channel layer 7b, thereby forming the gate insulating film 8a. The gate insulating film 8a can be formed by a method disclosed in Japanese Laid-Open Patent Publication No. 2005-136386, for example. The thickness of the gate insulating film 8a is determined by the operating voltage of the gate driving circuit. In view of the reliability of the gate insulating film 8a, where the gate insulating film 8a is made of SiO₂, it is normal to design with an electric field of about 3 MV/cm. Therefore, when the gate operating voltage is 20 V, the thickness of the gate insulating film 8a is about 70 nm.

Next, as shown in FIG. 6(d), the gate electrode 8b is formed on the gate insulating film 8a. The gate electrode 8b can be formed by depositing a polysilicon film which is deposited with a high concentration of an n-type impurity (phosphorus or antimony) and patterning the polysilicon film. The polysilicon film may be a film that contains a high concentration of a p-type impurity. Note that the thickness of the surface channel layer 7b is a thickness obtained by subtracting the amount of polish of CMP, the thickness of the sacrifice oxide film and the thickness of the oxide film from the grown semiconductor layer. The gate electrode 8b typically contains a phosphorus impurity at about 7×10²⁰ cm⁻³. The thickness may be about 500 nm. The formed gate electrode 8b is subjected to PS oxidation for activation. For example, a gate of a high reliability can be realized by performing a heat treatment at 900° C., in a dry oxygen atmosphere, under such a condition that an oxide film of 50 nm or more and 100 nm or less is grown.

Then, as shown in FIG. 6(e), the interlayer insulating film 9 made of a PSG film is formed, and a contact region is opened as shown in FIG. 6(f). The interlayer insulating film may be an oxide film which is deposited by HTO, plasma CVD, or the like.

As shown in FIG. 6(g), a Ti film or an Ni film is deposited as the electrode material of the source electrode 6, and patterned. Then, a heat treatment is performed at about 900° C. or more and about 1000° C. or less for realizing an ohmic contact. The contact resistance is about 10⁻⁵ Ωcm² or less. Then, as shown in FIG. 6(h), an Al film is deposited and patterned, thereby forming the source line 10 connecting together the source electrodes 6 of unit cells. Finally, as shown in FIG. 6(i), a Ti film or an Ni film is deposited on one surface (reverse surface) of the substrate 2 on which the drift layer 3 is not formed, and subjected to a heat treatment at about 900° C. or more and about 1000° C. or less, thereby forming the drain electrode 1. Thus, a double implanted MOSFET is completed.

Note that in the present embodiment, the impurity concentration of the fourth n-type impurity region 7d is equal to the impurity concentration of the drift layer 3. Where the impurity concentration of the fourth n-type impurity region 7d is set to be higher than the impurity concentration of the drift layer 3, it is preferred that the impurity concentration of the fourth n-type impurity region 7d is determined so that the reliability of the gate oxide film at the middle point between the p-type wells 4a of adjacent cells is ensured while the MOSFET 101 is in the OFF state and the drain voltage is maintained.

### Second Embodiment

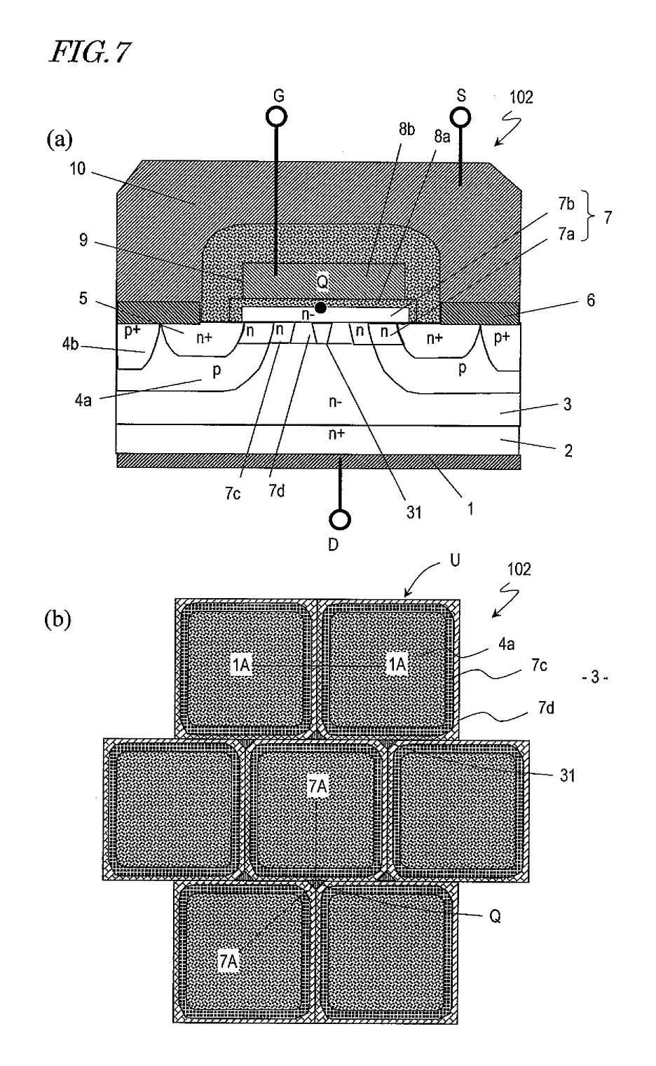

A semiconductor device according to a second embodiment of the present invention will now be described. FIG. 7(a) shows a partial cross-sectional structure of a double implanted MOSFET 102, and FIG. 7(b) shows a plan view at the drift layer 3 of the MOSFET 102. FIG. 7(a) shows a cross-sectional structure taken along line 7A-7A in FIG. 7(b). In FIG. 7(b), the cross-sectional structure taken along line 1A-1A is the same as that of the first embodiment. As in the first embodiment, the MOSFET 102 includes a plurality of unit cells U, each unit cell U has a rectangular shape on the drift layer 3, and the rectangular shapes are arranged in a staggered pattern.

As shown in FIGS. 7(a) and 7(b), the MOSFET 102 is different from the first embodiment in that it further includes a fifth n-type impurity region 31 at a position in the drift layer 3 that is adjacent to the fourth n-type impurity region 7d and that includes an apex of the unit cell U. The impurity concentration of the fifth n-type impurity region 31 is set to be lower than the impurity concentration of the fourth n-type impurity region 7d.

Repeating a statement above, the impurity concentration of the fourth n-type impurity region 7d is set to be lower than the impurity concentration of the third n-type impurity region 7c. After effectively reducing the channel resistance by setting the concentration as described above, it is possible to improve the reliability at the point P in the middle between the wells 4. That is, it is possible to effectively avoid the electric field localization at the point P which occurs when a large voltage is applied to the drain.

As shown in FIG. 7(b), the distance between the wells 4a of two adjacent unit cells U is longer at a position passing through an apex of a unit cell U (the position of line 7A-7A) than at a position where the adjacent unit cells U are in contact with each other along a side thereof (the position of line 1A-1A). Therefore, even if the impurity concentration of the fourth n-type impurity region 7d is set so that the drift layer 3 is depleted completely at the position where adjacent unit cells U are in contact with each other along a side thereof while the MOSFET 102 is in the OFF state and the drain voltage is applied, the depletion layer from the well 4a does not reach the vicinity of a point Q which is an apex of a unit cell U. Therefore, the localization of an electric field may occur at the point Q.

Therefore, in the present embodiment, the impurity concentration of the fifth n-type impurity region 31 is set to be smaller than the fourth n-type impurity region 7d. More preferably, the impurity concentration of the fifth n-type impurity region is set to be smaller than the concentration of the fourth impurity region so that the fifth n-type impurity region is depleted before the fourth n-type impurity region is depleted when a voltage is applied to the drain electrode 1 of the MOSFET 102. Therefore, even if the distance between the wells 4a of two adjacent unit cells U is long at a position passing through the point Q which is an apex of a unit cell U (the position of line 7A-7A), when the drift layer 3 is depleted at the position where adjacent unit cells U are in contact with each other along a side thereof, the drift layer 3 can be depleted also in the vicinity of the point Q which is an apex of a unit cell U. Therefore, it is possible to suppress the localization of an electric field at the point Q while the MOSFET 102 is in the OFF state and the drain voltage is applied. As a result, it is possible to suppress the increase in the drain leak in the OFF state, and to suppress the occurrence of a decrease in the breakdown voltage. Moreover, it is possible to suppress an increase in the leak through the gate insulating film or the breakdown of the gate insulating film due to a high drain electric field, and it is also possible to suppress the decrease in the threshold voltage.

### Experiment Example

The results of an experiment on how the channel resistance is influenced when the impurity concentrations of the third n-type impurity region and the well are varied in the MOSFET 101 of the first embodiment will now be described.

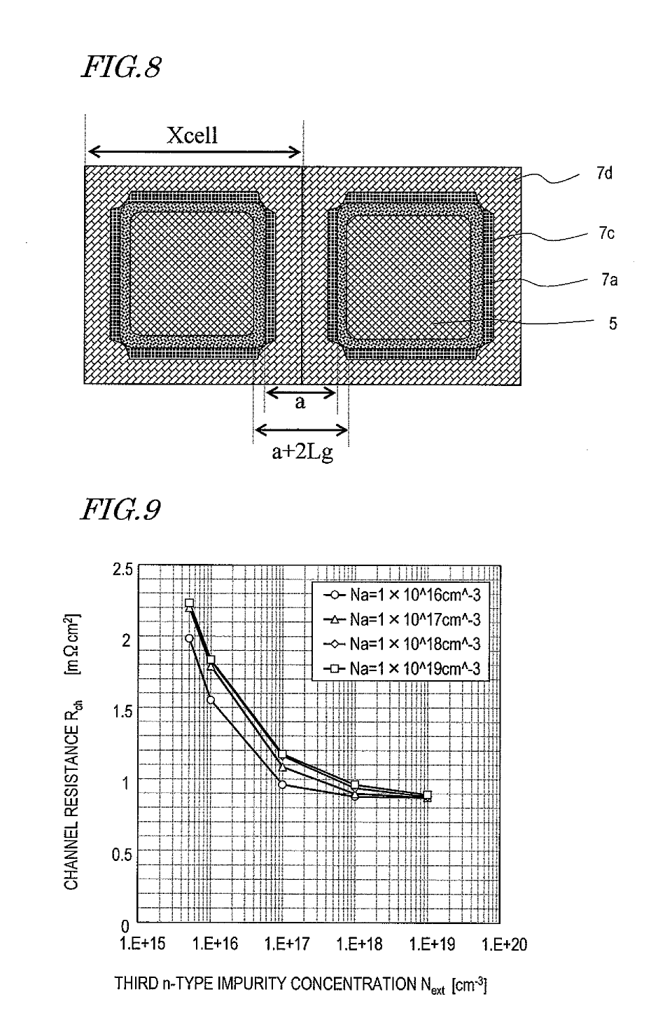

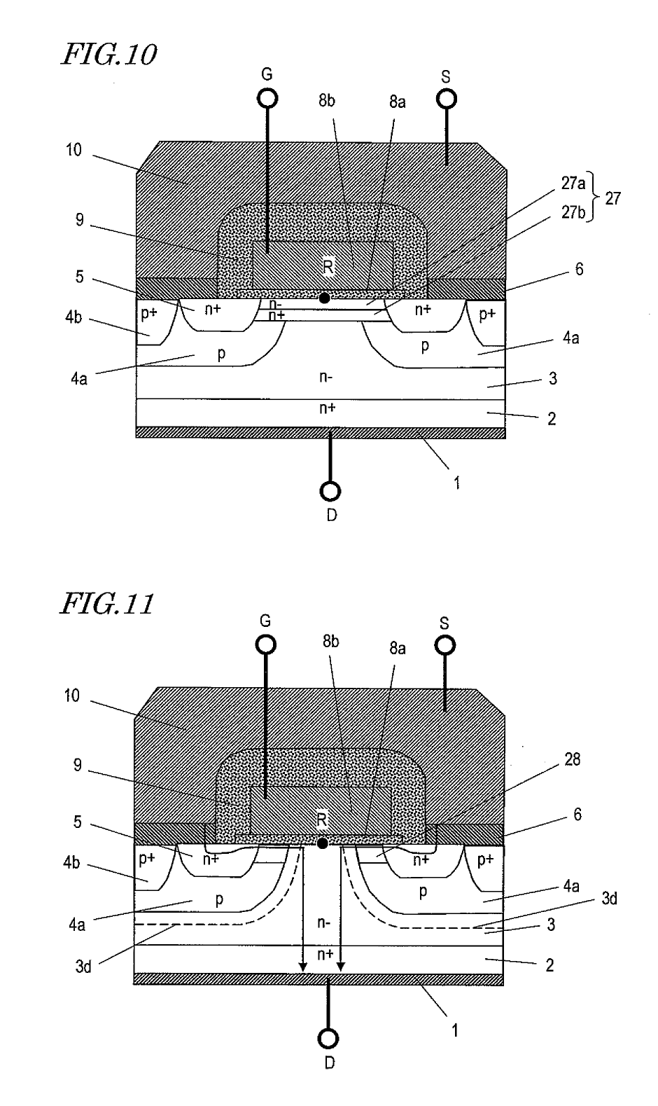

As shown in FIG. 8, Xcell denotes the size of a unit cell, and a+2Lg and a respectively denote the distance between the first n-type impurity regions 5 of two adjacent unit cells and the distance between the second n-type impurity regions 7a in the direction in which the unit cells are arranged. The width of the second n-type impurity region 7a in the direction in which the unit cells are arranged is denoted as Lg which is the channel length. Table 1 shows values used in the calculation.

TABLE 1

| Item | Symbol | Unit | Value |
|---|---|---|---|
| Unit cell size | Xcell | μm | 9.6 |
| Interval between second n-type im- | a | μm | 3 |
| purity regions 7a | | | |
| Interval between first n-type im- | a + 2Lg | μm | 4 |
| purity regions 5 | | | |
| Impurity concentration of well 4 | Na | cm⁻³ | — |
| Impurity concentration of third n- | Next | cm⁻³ | — |
| type impurity region 7c | | | |

FIG. 9 shows the results of calculating the channel resistance R_{ch} [mΩcm²] when the carrier concentration Na of the first n-type impurity region 5 and the impurity concentration Nₑₓₜ of the third n-type impurity region 7c are varied. The channel resistance R_{ch} was calculated assuming that the effective channel mobility was 39.3 cm²/Vs. This value is a value which was obtained by using a channel including a gate insulating film which was obtained by forming a silicon oxide film by oxidizing the surface of an epitaxially-grown silicon carbide semiconductor layer and then further nitriding the silicon oxide film. Similar results are obtained also when using the effective channel mobility based on other insulating films. The threshold value of the MOSFET 101 was 7 V, and the channel resistance R_{ch} was obtained while a voltage of 20 V was applied to the gate. The operating temperature was set to 200° C.

As can be seen from FIG. 9, the channel resistance R_{ch} decreases and converges to 0.9 mΩcm² as the impurity concentration of the third n-type impurity region increases, independent of the impurity concentration of the well 4. This value is what the channel resistance value should be for the channel length Lg=0.5 μm where the extension of the channel length due to the formation of the depletion layer does not occur.

In contrast, if the impurity concentration Nₑₓₜ of the third n-type impurity region 7c is similar to that of the drift layer 3, i.e., in the range of 5×10¹⁵ cm⁻³ to 1×10¹⁶ cm⁻³, and the impurity concentration Na of the well is 1×10¹⁷ cm⁻³ or more, the channel resistance R_{ch} will be 1.8 mΩcm² or more, which is equal to or more than twice what the channel resistance should be.

Thus, it can be seen that the impurity concentration of the third n-type impurity region 7c is preferably set to 1×10¹⁶ cm⁻³ or more in order to significantly reduce the channel resistance.

In order to reduce the channel resistance, it is preferred that the impurity concentration Nₑₓₜ of the third n-type impurity region 7c is as high as possible. However, if the impurity concentration Nₑₓₜ is set to 10¹⁸ cm⁻³ or more, a high electric field is applied to the third n-type impurity region 7c when a high voltage is applied to the drain. This is disadvantageous for the OFF characteristics, causing a decrease in the breakdown voltage and an increase in the leak current. In order to decrease the electric field intensity of the gate oxide film at the point P in FIG. 1 where the electric field is highest in the OFF state, the impurity concentration Nₑₓₜ of the third n-type impurity region 7c is more preferably set to 10¹⁷ cm⁻³ or less. As can be seen from FIG. 9, the increase of the channel resistance is not so significant when the impurity concentration Nₑₓₜ is set to about 10¹⁷ cm⁻³ to about 10¹⁸ cm⁻³. Therefore, it can be seen that it is possible to make characteristics improvements which have conventionally been thought to be difficult to achieve both at the same time, i.e., to improve the OFF characteristics of a MOSFET while reducing the channel resistance.

Note that while the silicon carbide substrate and the drift layer are of the n-type in the first and second embodiments, effects described above in the first and second embodiments are also realized with a MOSFET that uses a silicon carbide substrate and a drift layer of the p-type and has a structure in which the conductivity type is reversed from the first and second embodiments. The present invention is not limited to MOSFETs, and similar effects can be obtained also when a structure of the present invention is employed with an IGBT.

### INDUSTRIAL APPLICABILITY

The present invention is suitably used in power MOSFETs and various control devices and driving devices using power MOSFETs.

### REFERENCE SIGNS LIST

1 Drain electrode
2 Substrate
3 Drift layer
4a Well
4b Contact layer
5 Source region
6 Source electrode
7 Channel
7a Second n-type impurity region
7b Surface channel layer
7c Third n-type impurity region
7d Fourth n-type impurity region
8a Gate insulating film
8b Gate electrode
9 Interlayer insulating film
10 Source line
27a First epitaxial layer
27b Second epitaxial layer
30 Region between P-type wells
31 Fifth n-type impurity region
50 Well mask
52, 53, 54 Mask

1. A semiconductor device including a plurality of unit cells arranged at least one-dimensionally, each unit cell comprising:
a substrate made of an n-type wide bandgap semiconductor;
a drift layer formed on the substrate and made of the n-type wide bandgap semiconductor;
a p-type well provided in the drift layer;
a first n-type impurity region provided in the well;
a surface channel layer formed at least on a surface of the well so as to connect together the first n-type impurity region and the drift layer;
a second n-type impurity region provided in a surface region of the well which is under the surface channel layer and which spans the first n-type impurity region and the drift layer, the second n-type impurity region having an impurity concentration generally equal to or greater than an impurity concentration of the well;
a third n-type impurity region formed in a surface region of the drift layer adjacent to the second n-type impurity region;
a gate insulating film formed on the surface channel layer;
a gate electrode formed on the gate insulating film;
a source electrode electrically connected to the first n-type impurity region; and
a drain electrode provided on one surface of the substrate which is opposite to a surface thereof on which the drift layer is formed,
wherein a depletion layer is formed in the drift layer by contacting the well with the drift layer, and the depletion layer does not extend to an end of the third n-type impurity region.

2. The semiconductor device according to claim 1, wherein a depth of the third n-type impurity region is smaller than a depth of the first n-type impurity region.

3. The semiconductor device according to claim 2, wherein a depth of the third n-type impurity region is smaller than a width of the second n-type impurity region in a direction in which the plurality of unit cells are arranged.

4. The semiconductor device according to claim 3, wherein:
each unit cell includes a fourth n-type impurity region formed in a surface region of the drift layer between the third n-type impurity region and a third n-type impurity region of an adjacent unit cell; and
an impurity concentration of the fourth n-type impurity region is lower than an impurity concentration of the third n-type impurity region and is generally equal to or greater than an impurity concentration of the drift layer.

5. The semiconductor device according to claim 4, wherein:
the semiconductor device further includes a fifth n-type impurity region formed at a position in the drift layer that is adjacent to the fourth n-type impurity region and that includes an apex of the unit cell; and
an impurity concentration of the fifth n-type impurity region is lower than the impurity concentration of the fourth n-type impurity region.

6. The semiconductor device according to claim 5, wherein as each unit cell is seen from a surface side of the drift layer, the well has a generally rectangular shape, and the third n-type impurity region is not provided at corners of the rectangular shape of the well.

7. The semiconductor device according to claim 5, wherein as each unit cell is seen from a surface side of the drift layer, the third n-type impurity region continuously surrounds the well.

8. The semiconductor device according to claim 1, wherein a depth of the third n-type impurity region is smaller than a depth of the well.

9. The semiconductor device according to claim 1, wherein:
the semiconductor device further includes a contact region in the p-type well; and
a depth of the second n-type impurity region is smaller than a depth of the contact region.

10. The semiconductor device according to claim 1, wherein an expression:
$$Lg ≧ \sqrt{\frac{2 \cdot ɛ \cdot Na \cdot Vbi}{q \cdot Next \cdot ( Na + Next )}} \qquad [ Expression 1 ]$$
is satisfied, where Nₑₓₜ denotes an impurity concentration of the third n-type impurity region, Na denotes the impurity concentration of the well, ∈ denotes a relative dielectric constant of silicon carbide, q denotes an elementary electric charge, Vbi denotes an internal potential of a junction portion between the second n-type impurity region and the third n-type impurity region, and Lg denotes a channel length of a channel formed in the surface channel layer.

11. The semiconductor device according to claim 1, wherein an impurity concentration of the third n-type impurity region gradually decreases away from the second n-type impurity region in a direction in which the plurality of unit cells are arranged.

12. The semiconductor device according to claim 1, wherein a concentration of the third n-type impurity region gradually decreases away from a surface of the drift layer.

13. The semiconductor device according to claim 1, wherein the surface channel layer contains an n-type impurity.

14. The semiconductor device according to claim 1, wherein the surface channel layer contains a p-type impurity.

15. The semiconductor device according to claim 13, wherein an impurity concentration of the n-type impurity of the surface channel layer is 1×10¹⁶ cm⁻³ or less.

16. A method for manufacturing a semiconductor device, comprising the steps of:
(A) preparing a substrate made of an n-type wide bandgap semiconductor on which a drift layer made of an n-type wide bandgap semiconductor is provided;
(B) forming a well mask on the drift layer;
(C) forming a p-type well in the drift layer by implanting a p-type impurity using the well mask;
(D) implanting an n-type impurity using the well mask from a vertical direction and from an inclined direction with respect to the substrate, thereby forming an impurity region in the drift layer, the impurity region including a region to be a first n-type impurity region and a second n-type impurity region, and forming a third n-type impurity region in a portion of the drift layer under the well mask;
(E) forming a first n-type impurity region mask on the drift layer in a self-aligned manner with respect to the well mask;
(F) implanting an n-type impurity using the first n-type impurity region mask, thereby forming the first n-type impurity region in the drift layer, thus delimiting the second n-type impurity region;
(G) removing the first n-type impurity region mask and the well mask;
(H) performing an activation annealing process on the drift layer;
(I) forming a surface channel layer having a low impurity concentration by epitaxial growth on the second n-type impurity region and the third n-type impurity region so as to be in contact with the first n-type impurity region and the well;
(J) forming a gate insulating film on a surface of the surface channel layer;
(K) forming a gate electrode on the gate insulating film; and
(L) forming a source electrode and a drain electrode so as to be in contact with the first n-type impurity region and the substrate, respectively,
wherein a depletion layer is formed in the drift layer by contacting the well with the drift layer, and the depletion layer does not extend to an end of the third n-type impurity region.

17. The method for manufacturing a semiconductor device according to claim 16, wherein in the step (D), the third n-type impurity region is formed in the portion of the drift layer under the well mask by implanting the n-type impurity from a direction inclined with respect to the substrate within a plane perpendicular to a side that defines an opening shape of the well mask.

18. The method for manufacturing a semiconductor device according to claim 16, wherein in the step (D), the third n-type impurity region is formed in the portion of the drift layer under the well mask by continuously rotating the substrate while implanting the n-type impurity from a direction inclined with respect to the substrate.

19. The method for manufacturing a semiconductor device according to claim 16, wherein in the step (D), the third n-type impurity region is formed in the portion of the drift layer under the well mask by rotating the substrate stepwise while implanting the n-type impurity from a direction inclined with respect to the substrate.

20. The method for manufacturing a semiconductor device according to claim 16, wherein in the step (I), the surface channel layer is formed while an impurity gas other than a material gas of SiC is not intentionally supplied.

21. The method for manufacturing a semiconductor device according to claim 16, wherein in the step (I), the surface channel layer is formed while a material gas of SiC and a gas to be an n-type impurity or p-type impurity are supplied.

22. The semiconductor device according to claim 1, wherein the an impurity concentration of the third n-type impurity region is 1×10¹⁶ cm⁻³ or more and is less than 1×10¹⁸ cm⁻³.

23. The semiconductor device according to claim 1, wherein the an impurity concentration of the third n-type impurity region is 1×10¹⁶ cm⁻³ or more and is 1×10¹⁷ cm⁻³ or less.
